(19) United States
(12) Patent Application Publication
(10) Pub. No.: US 2015/0282361 A1
(43) Pub. Date: Oct. 1, 2015

(54) STRUCTURE AND A METHOD FOR SUPPRESSING AUDIO NOISE OF ELECTRONIC EQUIPMENT

(71) Applicant: HUIMIN CHEN, Taoyuan County (TW)

(72) Inventor: HUIMIN CHEN, Taoyuan County (TW)

(21) Appl. No.: 14/719,553

(22) Filed: May 22, 2015

Related U.S. Application Data
(63) Continuation-in-part of application No. 13/634,049, filed on Sep. 11, 2012, now abandoned.

(51) Int. Cl. H05K 5/03; C04B 35/48

(52) U.S. Cl. CPC H05K 5/03; C04B 35/481

(57) ABSTRACT

A structure and a method for suppressing audio noise of electronic equipment are carried out by utilizing an audio noise suppressing structure to cover a periphery or a surface of the electronic equipment or circuits thereof. The audio noise suppressing structure mainly comprises zirconia and at least one oxide serving as a stabilizer. The zirconia and the oxide are evenly mixed and sintered with a high temperature to form an electrically conductive ceramic body. In use, because the audio noise suppressing structure is disposed on a periphery or a surface of the electronic equipment or the audio circuits thereof, the electrification of the electronic equipment or audio circuits create shunt conductance, far infrared radiations and a resonance effect to reduce the thermal accumulation. Thus, the accumulated heat possibly caused by working the electronic equipment is reduced or fully dispersed, thereby attaining a decrease in the noise.

### CROSS-REFERENCE TO RELATED APPLICATION

This application is a continuation-in-part application of U.S. patent application Ser. No. 13/634,049, entitled “A STRUCTURE AND A METHOD FOR SUPPRESSING NOISE OF ELECTRONIC EQUIPMENT”, filed on Sep. 11, 2012, now pending.

### FIELD OF THE INVENTION

The present invention relates to an audio noise suppressing structure of electronic equipment and a method for suppressing the audio noise with the aid of the structure.

### DESCRIPTION OF THE RELATED ART

Recently, digital electronic equipment, such as mobile phones, digital cameras and laptops, is developed greatly. Herein, the aforesaid products generally require operating signals having high frequency, small dimension and light weight. However, since electronic parts or circuit boards are arranged in high density, techniques for developing the aforesaid products are in fact difficult.

Because the electronic parts or the circuit boards of the electronic equipment are arranged in high density, and the operating signals with a high frequency is developed, these factors render the electronic circuit unable to arrange a complete layout of a distance between parts where noise is generated and other parts. Therefore, a noise suppressing structure for suppressing electromagnetic noise generated or emitted by the electronic equipment, such as microprocessors, LSI, electronic couplings and LCD panels, is commonly attached to the electronic circuits, the circuit boards or the electronic couplings. However, if reflected waves created by the noise suppressing structure are too large, the reflected waves may interfere with the signals of the circuit transmission, and such interference may cause errors.

With respect to conventional audio components or devices, such as the player, the amplifier, the loudspeaker, the microphone, the earphone. the mobile communicator, the sound card, the audio apparatus, the electronic video device and the telecommunication line, the electronic signals transmitted by these components or devices are easily influenced by an external environment, such as the radio frequency (RF) in the air, the static electricity, the radiation and the noise generated in the transmission line, the electronic parts or circuits of the device. The aforesaid factors incur audio noise and cause a large decrease in the quality of the final audio signal or a distortion thereof.

Generally, the electronic audio signals in the audio or stereo equipment are usually processed by the circuits in an audio host, and transmission lines are used to send the electronic signals to an external amplifier. Because the internal circuits and the transmission lines possess the impedance, the capacitance and the inductance, these effects accumulate heat during the transmission. Accordingly, if a preferable mechanism for dispersing or reducing the accumulated heat is not provided, the accumulation of heat will effect a random movement of charge carriers of the circuit, such as electrons and holes. This random movement, called a “Brownian motion”, makes the transmission of the electronic signals in the circuits declined. As a result, the distortion and the noise are brought about.

Moreover, the influence of the aforesaid external environment and the accumulated heat generated in the internal electronic parts or circuits bring noise with different magnitude and amount to the electronic signals output from an electronic host, and this situation reduces the output quality of the signal. The aforesaid shortcomings can be solved by using transmission lines or circuits with high conductivity and a better shielding effect, but these specific transmission lines are quite expensive and are unpopular with general products. Thus, the prior art still needs improvements.

### SUMMARY OF THE INVENTION

The object of the present invention is to provide a structure and a method for suppressing audio noise of electronic equipment which applies a noise suppressing structure with a simple construction and a low cost to the electronic equipment, thereby reducing or repressing audio noise in the circuits and enhancing the quality of electronic audio signals transmitted by the electronic equipment or the circuit.

The method in accordance with the present invention for suppressing audio noise of electronic equipment is executed by utilizing an electrically conductive ceramic body to cover or attach to an outer periphery of an electronic equipment. The electrically conductive ceramic body is a ceramic covering body made by evenly mixing zirconia and at least one of other oxides together to form a mixture and sintering the mixture.

The aforesaid other oxides can include calcium oxide, magnesia, yttrium (III) oxide or a compound formed by the aforesaid elements.

The compositions of the audio noise suppressing structure of the electronic equipment comprises zirconia set in a range from 80 to 99 wt % and other oxide set in a range from 1 to 20 wt %. The oxide can adopt magnesia, calcium oxide and yttrium (III) oxide, or the oxide can adopt a compound formed by at least two of the aforesaid elements.

The ceramic covering body can be a sleeve, a shelter or a covering. the shape of which can be formed into a flake, a pillar, a spicule, a powdered body, a hollow column or a solid column.

A method for suppressing audio noise of electronic equipment (or circuits) is obtained by making a periphery or a surface of circuits shielded by an audio noise suppressing structure of an electronic equipment. The audio noise suppressing structure of the electronic equipment is made by steps of:

preparing a zirconia material(can be formed into powder) which is 80 to 99 percent by weight;

preparing a material of oxide stabilizer(can be formed into powder) which is 1 to 20 percent by weight percentage; and

evenly compounding the two materials into a compound material and proceeding to a sintering process for a ceramic treatment, thereby forming an electricity conductive ceramic body.

The sintering process includes a heating stage, a steady temperature stage and a cooling stage working sequentially. Wherein, the heating stage heats an operating temperature from a room temperature to a temperature between 1170° C. and 1850° C. within 8 hours to 14 hours. The steady temperature stage maintains the operating temperature at a certain temperature set between 1170° C. and 1850° C. for 1 hour to 4 hours. In the cooling stage, the operating temperature is decreased from the temperature between 1170° C. and 1850° C. to the room temperature within 11 hours to 15 hours. The electrically conductive ceramic body formed by the sintering process can be further crushed into powder. Alternatively, the compound material can be pressed into a form of a sleeve or a shelter prior to the sintering process.

Accordingly, the present invention provides the following advantages:

1. The audio noise suppressing structure of electronic equipment can be conveniently disposed on an outer periphery or a surface of the electronic equipment for reducing or repressing the noise around the electronic equipment or circuits.

2. When the electronic equipment is electrified, the audio noise suppressing structure of the electronic equipment or circuits causes shunt circuits resulting from a movement of oxide anions or causes far infrared radiations as well as a resonance effect, thereby increasing the heat conduction efficiency and the efficiency of dispersing the accumulated heat. Accordingly, the thermal accumulation which requires a high power operation can be prevented, and the efficiency of dispersing the heat accumulated in the electronic parts and the circuit of the electronic equipment can be promoted. Thus, the thermal noise resulting from the accumulated heat in the electronic equipment or circuits can be reduced or suppressed in order to increase the quality of the transmitted electronic audio signals.

3. The audio noise suppressing structure of electronic equipment is conveniently manufactured with a low cost. Therefore, the application of the structure is wider, and the structure is also available to general electronic products.

### BRIEF DESCRIPTION OF THE DRAWINGS

The description of the present invention will be described in detail by following embodiments and the accompanying drawings.

FIG. 1 is a schematic view showing the present invention applied to a transmission line;

FIG. 2 is a schematic view showing the present invention applied to a circuit board;

FIG. 3A is an oscillogram showing a change of the wave by using a system for testing digital electronic signals when the audio noise suppressing structure of the present invention is not used;

FIG. 3B is an oscillogram showing a change of the wave by using a system for testing digital electronic signals when the audio noise suppressing structure of the present invention is used;

FIG. 4A is a joint analysis showing the energy-time-frequency status by using a system for testing analogical electronic signals when the audio noise suppressing structure of the present invention is not used; and

FIG. 4B is a joint analysis on the energy-time-frequency status by using a system for testing analogical electronic signals when the audio noise suppressing structure of the present invention is used.

### DETAILED DESCRIPTION OF THE PREFERRED EMBODIMENTS

The advantages of the present invention over the known prior art will become more apparent upon reading the following descriptions in conjunction with the accompanying drawings.

A method for suppressing audio noise of electronic equipment utilizes an electrically conductive ceramic body to shield an outer periphery of an electronic equipment. Wherein, the electrically conductive ceramic body is formed by combining zirconia with other oxides in a certain proportion and carrying out a sintering process to form an ionized electrically conductive ceramic body whose physical property such as magnetism or frequency, is changed. When an audio noise suppressing structure is disposed on an outer periphery or a surface of a circuit, the suppressing structure can reduce or suppress the audio noise going by the electronic equipment. Moreover, when the circuit of the electronic equipment is electrified, the use of the audio noise suppressing structure further attains a shunt path, generates a resonance effect and radiates far infrared rays to eliminate the thermal accumulation in the circuit of the electronic equipment and further attain the effect of promoting the heat dispersion and reducing the thermal noise. Therefore, the quality of the electronic audio signals transmitted by the circuit of the electronic equipment is preferably enhanced.

The structure and the method for suppressing audio noise of electronic equipment in accordance with the present invention can be applied to general circuits for transmitting audio signals, e.g. parts related to circuit boards and lines, and can also be applied to video and audio signal treating or transmitting parts or devices and audio components or devices, such as the player, the amplifier, the loudspeaker, the microphone, the ear phone, the mobile communicator, the sound card, the audio apparatus and the circuits of telecommunication lines. The following embodiments take the audio component as an example for explanation. It should be noted that the processing and the transmission of the audio electronic signals and those of the video signals are in common. Thus, the electronic signal noise suppressor that is adapted to the audio field is also adapted to the video system. Therefore, the similar functions and correlations are omitted.

The audio noise suppressing structure in accordance with the present invention is mainly an electrically conductive ceramic body that mainly includes zirconia (ZrO2) and further includes other oxides as a stabilizer, such as yttrium (III) oxide (Y2O3), calcium oxide (CaO), magnesia (MgO) and other oxides. A combination of the aforesaid oxides is also available. The audio noise suppressing structure of the present invention can have other components besides the aforesaid elements. Also, the aforesaid listed elements have their distinguishing properties. In the preferred embodiments, the electrically conductive ceramic body of the audio noise suppressing structure of the present invention is mainly constituted by the following proportions as defined in percent by weight (wt %) for each possible component:

First preferred embodiment: zirconia is 80 to 99 wt %, and magnesia is 1 to 20 wt %;

Second preferred embodiment: zirconia is 80 to 99 wt %, and calcium oxide is 1 to 20 wt %;

Third preferred embodiment: zirconia is 80 to 99 wt %, and yttrium (II) oxide is 1 to 20 wt %;

Fourth preferred embodiment: zirconia is 80 to 99 wt %, magnesia is 1 to 19 wt %, and calcium oxide is 1 to 19 wt %;

Fifth preferred embodiment: zirconia is 80 to 99 wt %, magnesia is 1 to 19 wt %, and yttrium (III) oxide is 1 to 19 wt %;

Sixth preferred embodiment: zirconia is 80 to 99 wt %, calcium magnesium oxide is 1 to 19 wt %, and yttrium (III) oxide is 1 to 19 wt %; and

Seventh preferred embodiment: zirconia is 80 to 99 wt %, magnesia is 1 to 18 wt %, calcium oxide is 1 to 18 wt %, and yttrium (III) oxide is 1 to 18 wt %.

From the aforesaid seven embodiments, a process of making the audio noise suppressing structure comprises following steps:

Firstly, adopt part or all of the aforesaid elements and evenly compound the adopted elements in the certain proportion. Secondly, the compounded elements are pre-pressed into a desired formation (e.g. a flake shape). This pressing step can be achieved with the aid of a mold or a processor. The evenly-compounded elements are pressed into a shaped material with various shapes according to the practical application. The material can be formed in an annular shape, a laminar shape (e.g. a thin flake, a curved sheet and a flat sheet), a pillar shape, an acicular shape, a hollow column, a solid column, a granular shape or other geometrical shapes. Subsequently, the shaped material is conveyed to a high-temperature furnace, such as a tunnel furnace, for sintering until it becomes ceramic. Therefore, the audio noise suppressing structure of the electronic equipment is made.

In the aforesaid embodiments, the sintering process includes a heating stage, a steady temperature stage and a cooling stage in sequence. Wherein, in the heating stage, an operating temperature in the furnace is raised from a room temperature to a temperature between 1170° C. and 1850° C. within 8 hours to 14 hours. In the steady temperature stage, the operating temperature is maintained at a certain fixed temperature between 1170° C. and 1850° C. for about 1 to 4 hours. In the cooling stage, the operating temperature is decreased from the temperature between 1170° C. and 1850° C. to the room temperature within about 11 to 15 hours. Accordingly, the sintering process is completed.

It should be noted that the operating temperature between 1170° C. and 1850° C. is the preferred temperature for the sintering process in the aforesaid embodiments. In the practical application, the sintering temperature can be freely adjusted. Other temperature is applicable as long as the zirconia and other compound, e.g. other oxides, are fully treated under the temperature to become ceramic. Wherein, the sintered audio noise suppressing structure can directly cover or attach to an outer periphery and a peripheral surface of the electronic equipment, circuits or lines. It is also possible that the audio noise suppressing structure is crushed or milled into powder so that the surface of the electronic equipment or the circuits where the audio noise of electronic signals needs to be suppressed can be coated with the powder. Alternatively, glue or adhesive tape can be used to allow the sintered powder or flake-shaped body to be adhered to the surface of the electronic equipment or the circuits where the audio noise of electronic signals needs to be suppressed. The aforesaid surface, for example, may be the surface of the circuits on the circuit boards or the outer surface of electronic couplings of lines or ends of the lines.

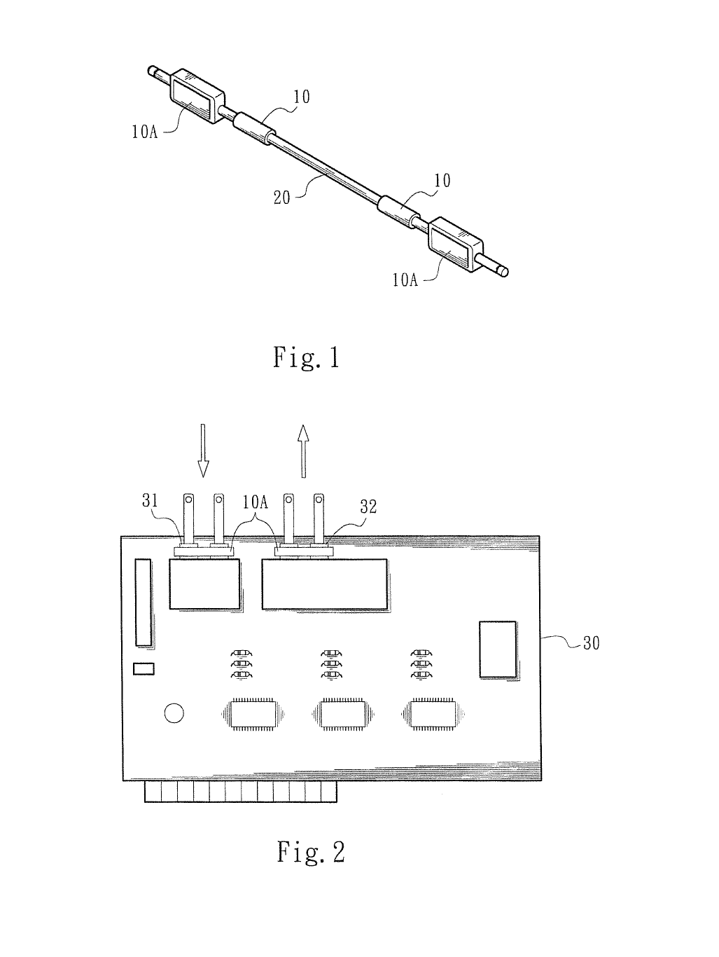

Referring to FIG. 1, the present invention is practically utilized. An audio noise suppressing structure 10 is designed in a form of a sleeve or a shelter, such as a ring sleeve or a flexible flake, for covering a periphery of a general transmission line 20. As shown in the figure, the sleeve or the shelter is pressed into an annular shape and sleevedly disposed on ends or a middle part of the transmission line 20. Two ends of the transmission line 20 are respectively connected to a host of the electronic equipment (such as a stereo host) and an external amplifier or a loudspeaker. Herein, since the audio noise suppressing structure 10 becomes ceramic, the use of the suppressing structure 10 creates the aforesaid shunt path, a resonance effect or far infrared radiations to disperse heat while the electronic equipment is electrified. Therefore, when electronic audio signals are transmitted by the transmission line 20, the generation of audio noise near the transmission line 20, which results from the accumulation of heat, can be reduced or suppressed. In other words, when the audio noise suppressing structure 10 of the electronic equipment is installed on the transmission line 20 connected between the stereo host and the amplifier, the audio noise suppressing structure 10 can filter out audio noise from electronic signals in a small signal range. When the audio noise suppressing structure 10 is installed on the transmission line 20 connected between the amplifier and the loudspeaker, the audio noise suppressing structure 10 can also filter out noise existing in a wave of electronic audio signals from the electronic signals which are processed by the amplifier. Then, these electronic audio signals are sent to the loudspeaker.

Referring to FIG. 2, the audio noise suppressing structure 10 of the present invention is applied to a circuit board 30. Herein, the audio noise suppressor 10A that is formed into a strip or a flake is fixed or attached to a connector 31 at an input port of the circuit board 30 and another connector 32 at an output port of the circuit board 30. Accordingly, the noise of the electronic audio signal in the circuit board 30 can be filtered out or restrained. In order to expand the practical application of the audio noise suppressing structure 10, the audio noise suppressing structure 10 can be in a form of a plate, a strip, a flake or powder and can be respectively applied to surfaces of an integrated circuit, a metal coil and a circuit layout on the circuit board 30.

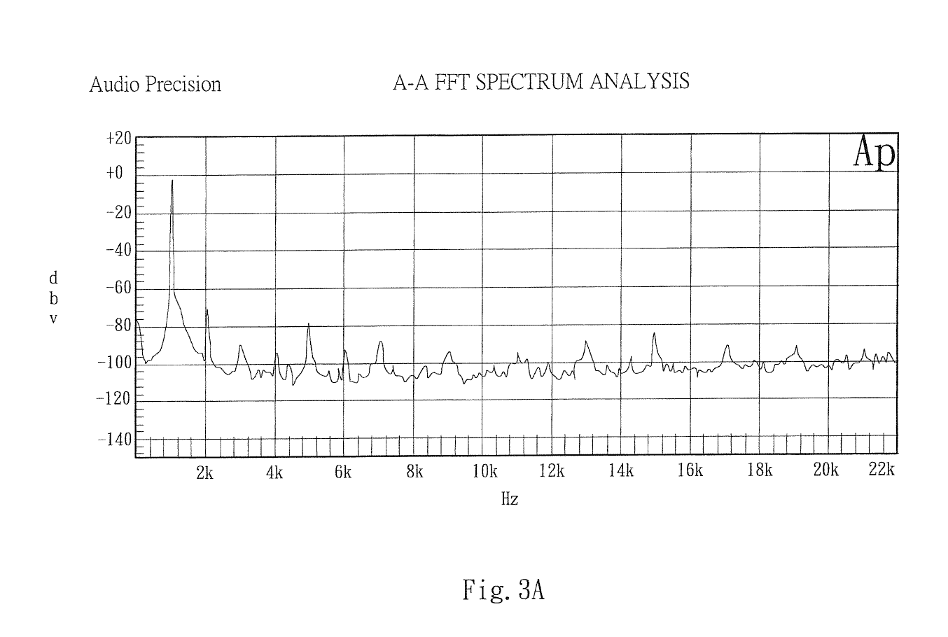

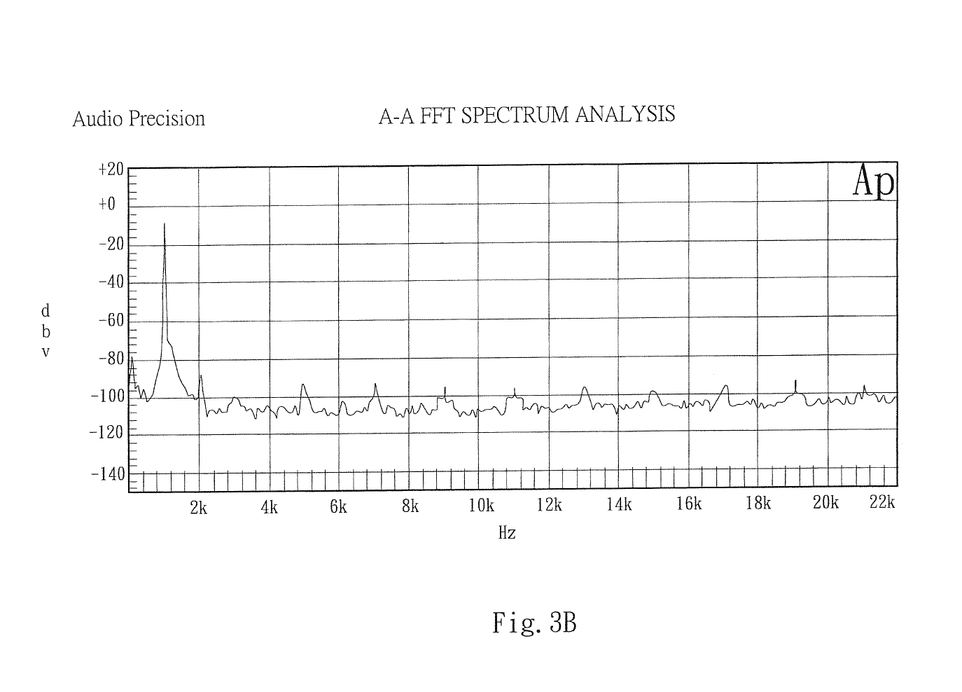

In order to testify that the audio noise suppressing structure of the present invention obtains the audio noise suppression of the electronic equipment, a comparison between the noise magnitude before applying the present invention and after applying the present invention is made by an Audio Precision System of Audio Precision Inc. in the United States. FIGS. 3A and 3B show testing results of the digital electronic audio signal affected by the audio noise suppressing structure of the present invention. FIG. 3A shows the tested object unequipped with the audio noise suppressing structure, and FIG. 3B shows the tested object equipped with the audio noise suppressing structure. A computer transmits a digital electronic audio signal to an MP3 player via a first transmission line and a Universal Serial Bus (USB) (not shown). When the digital electronic signal is transmitted to the MP3 player and processed, an analogical electronic audio signal is generated accordingly. Thereafter, the amplifier amplifies the signal, and a second transmission line transmits the amplified signal to the audio precision system to conduct a frequency domain analysis. Hence, the analysis is sent back to the computer. The comparing results can be evidently shown in FIG. 3A which does not use the audio noise suppressing structure and FIG. 3B which combines the audio noise suppressing structure with the USB. Obviously, when the audio noise suppressing structure of the present invention is applied, the noise magnitude is significantly reduced. To show distinguishing differences between the comparing results, Form 1 is provided for showing the test data in FIG. 3A and FIG. 3B.

Form 1

| | NOISE MAGNITUDE OF | NOISE MAGNITUDE OF |
|---|---|---|
| | THE EXPERIMENT | THE EXPERIMENT |
| | UNEQUIPPED WITH | EQUIPPED |
| | THE AUDIO | WITH THE AUDIO |
| | NOISE SUPPRESSING | NOISE SUPPRESSING |
| | STRUCTURE OF THE | STRUCTURE OF |
| | ELECTRONIC | THE ELECTRONIC |
| | EQUIPMENT | EQUIPMENT |
| FREQUENCY(HZ) | (dBV) | (dBV) |
| 2K | −72 | −88 |
| 5K | −79 | −92 |
| 13K | −90 | −96 |
| 15K | −82 | −98 |
| 18K | −102 | −108 |

Form 1 presents that when the electronic equipment is equipped with the audio noise suppressing structure, the noise magnitude is much less than that of the electronic equipment unequipped with the audio noise suppressing structure.

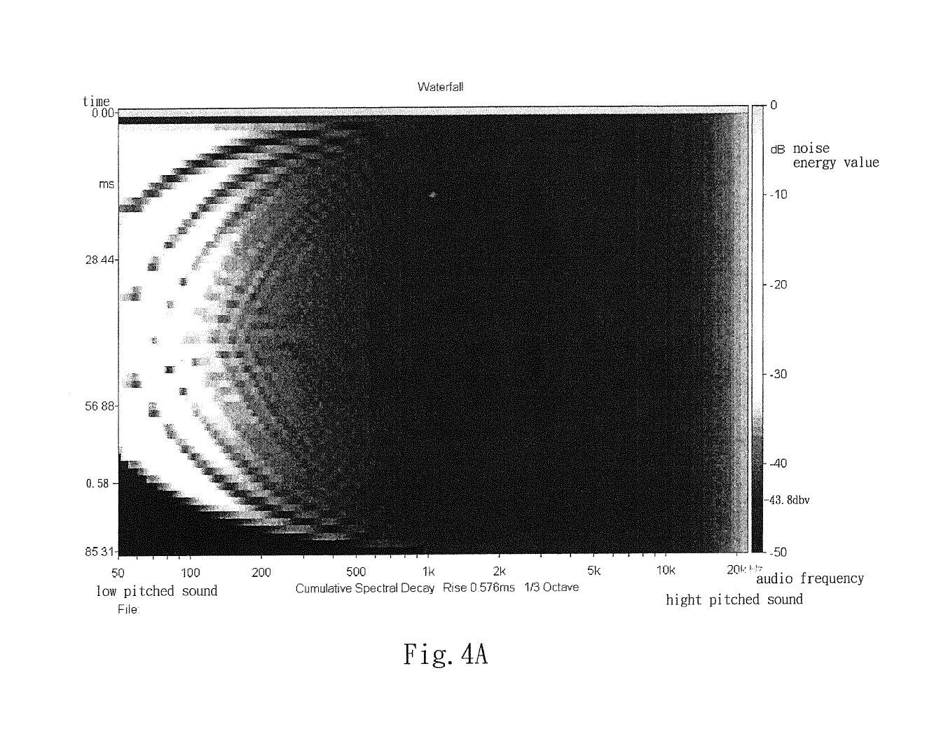

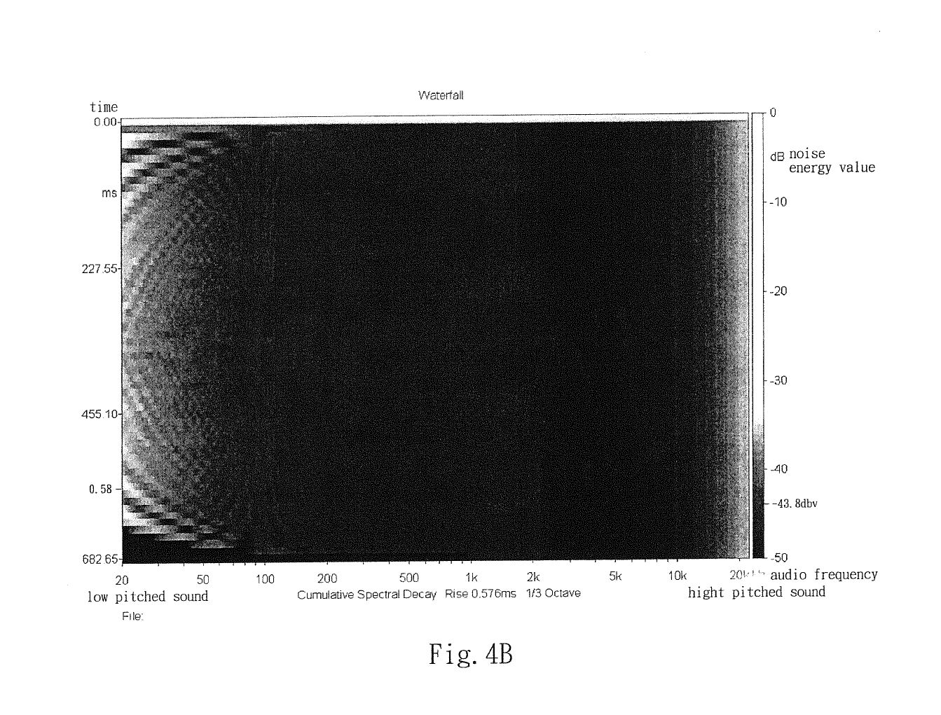

Further, FIGS. 4A and 4B respectively show the comparing results of the analogical electronic signal affected by the audio noise suppressing structure of the present invention. Wherein, the analogical electronic signal is output by a signal generator of an audio or frequency testing instrument, namely an IEA EA-A Electro-Acoustic Integrated System made in Italy, under the control of a computer. Further, the first transmission line transmits the analogical signal to a circuit where the audio noise suppressing structure of the present invention is installed . Thereafter, the analogical electronic signal is further transmitted back to the testing instrument for carrying out a joint energy-time-frequency analysis. Afterward, the analyzed data is sent back to the computer. FIG. 4A shows the status of the tested object unequipped with the audio noise suppressing structure of the present invention. Herein, when a frequency band is set between 500 and 7000 Hz, the energy is at −41.8 dBV. Relatively, FIG. 4B shows the status of the tested object equipped with the audio noise suppressing structure of the present invention. Wherein, even the frequency band is enlarged to 300-8000 Hz, the energy is only −43.8 dBV. Obviously, the use of the audio noise suppressing structure of the present invention is able to reduce the dynamic energy change, decrease the energy consumption and improve the clarity of the audio signal (or the audio analogical signal).

Accordingly, the aforesaid data show that the noise of the circuits or the lines is evidently reduced by the audio noise suppressing structure of the present invention to make the sound clearer.

While the embodiments of the present invention are shown and described above, it is understood that further variations and modifications may be made without departing from the scope of the present invention.

I claim:

1. An audio noise suppressing structure of electronic equipment comprising an electrically conductive ceramic body which covers an outer periphery of an electronic equipment, said electrically conductive ceramic body being formed by main components which comprise zirconia and at least one oxide that serves as a stabilizer, said electrically conductive ceramic body being a covering body formed by evenly mixing said main components to form a mixture and sintering said mixture with a high temperature to become ceramic, said zirconia being set in a range from 80 to 99 wt %, said stabilizer being set in a range from 1 to 20 wt %.

2. The audio noise suppressing structure of the electronic equipment as claimed in claim 1, wherein said oxide serving as said stabilizer is calcium oxide, magnesia, yttrium (III) oxide or a compound thereof.

3. The audio noise suppressing structure of the electronic equipment as claimed in claim 1, wherein said stabilizer is formed by compounding at least two elements from magnesia, calcium oxide and yttrium (III) oxide.

4. The audio noise suppressing structure of the electronic equipment as claimed in claim 1, wherein said electrically conductive ceramic body is a sleeve or a shelter that covers an outer surface of said electronic equipment.

5. The audio noise suppressing structure of the electronic equipment as claimed in claim 2, wherein said electrically conductive ceramic body is a sleeve or a shelter that covers an outer surface of said electronic equipment.

6. The audio noise suppressing structure of the electronic equipment as claimed in claim 3, wherein said electrically conductive ceramic body is a sleeve or a shelter that covers an outer surface of said electronic equipment.

7. The audio noise suppressing structure of the electronic equipment as claimed in claim 1, wherein said electrically conductive ceramic body is a flake-shaped body.

8. The audio noise suppressing structure of the electronic equipment as claimed in claim 2, wherein said electrically conductive ceramic body is a flake-shaped body.

9. The audio noise suppressing structure of the electronic equipment as claimed in claim 3, wherein said electrically conductive ceramic body is a flake-shaped body.

10. The audio noise suppressing structure as claimed in claim 1 , wherein said electrically conductive ceramic body is a pillar-shaped body.

11. The audio noise suppressing structure as claimed in claim 1, wherein said electrically conductive ceramic body is a powdered body.

12. A method for suppressing audio noise of electronic equipment, wherein said method is executed by using an audio noise suppressing structure of an electronic equipment to cover an outer periphery or a surface of said electronic equipment or circuits thereof, said audio noise suppressing structure of said electronic equipment being made by steps of:
preparing a zirconia material in a range from 80 to 99 percent by weight;
preparing a material of oxide stabilizer in a range from 1 to 20 percent by weight; and
evenly compounding said two materials into a compound material and subjecting said compound material to a sintering process to become ceramic, thereby forming an electricity conductive ceramic body.

13. The method as claimed in claim 12, wherein said sintering process includes a heating stage, a steady temperature stage and a cooling stage working in sequence.

14. The method as claimed in claim 13, wherein in said heating stage, an operating temperature is increased from a room temperature to 1170° C.˜1850° C. within 8 hours to 14 hours.

15. The method as claimed in claim 13, wherein in said steady temperature stage, an operating temperature is maintained at a fixed temperature between 1170° C. and 1850° C. for 1 hour to 4 hours.

16. The method as claimed in claim 13, wherein in said cooling stage, an operating temperature is decreased from 1170° C.˜1850° C. to a room temperature within 11 hours to 15 hours.

17. The method as claimed in claim 12, wherein said compound material is pressed into a sleeve or a shelter before said sintering process is conducted.

18. The method as claimed in claim 13, wherein said compound material is pressed into a sleeve or a shelter before said sintering process is conducted.

19. The method as claimed in claim 12, wherein said electrically conductive ceramic body subjected to said sintering process is crushed into powder.

20. The method as claimed in claim 13, wherein said electrically conductive ceramic body subjected to said sintering process is crushed into powder.
